(19) United States
(12) Patent Application Publication
(10) Pub. No.: US 2025/0323637 A1
(43) Pub. Date: Oct. 16, 2025

(54) SEMICONDUCTOR SWITCH

(71) Applicants: Kabushiki Kaisha Toshiba, Tokyo (JP); Toshiba Electronic Devices & Storage Corporation, Tokyo (JP)

(72) Inventor: Yukio TSUNETSUGU, Yokohama Kanagawa (JP)

(21) Appl. No.: 18/888,108

(22) Filed: Sep. 17, 2024

(30) Foreign Application Priority Data
Apr. 10, 2024 (JP) 2024-063628

(51) Int. Cl. H03K 17/0812; H03K 17/08

(52) U.S. Cl. CPC H03K 17/08122; H03K 2017/0806

(57) ABSTRACT

A semiconductor switch includes an electromotive force generation circuit that generates an electromotive force by receiving light, a first switching transistor that is connected between a first output terminal and a reference voltage node and drives a load when the electromotive force is generated, a second switching transistor that is connected between a second output terminal and the reference voltage node and drives the load when the electromotive force is generated, and a protection circuit that protects the first switching transistor and the second switching transistor from overcurrent and overheating using the electromotive force as a power supply voltage.

### CROSS REFERENCE TO RELATED APPLICATIONS

This application is based upon and claims the benefit of priority from the prior Japanese Patent Application No. 2024-063628, filed on Apr. 10, 2024, the entire contents of which are incorporated herein by reference.

### FIELD

Embodiments of the present invention relate to a semiconductor switch.

### BACKGROUND

A photo relay has several operation modes, and one of them is a solar cell mode. In the solar cell mode, a slight electromotive force generated by light emission of a light emitting diode (LED) in the photo relay is used to turn on a switching transistor to drive a load.

In order to control ON/OFF of the switching transistor, a timer for determining ON/OFF timing is required. Although the timer can be configured by a digital circuit or an analog circuit, a current that can flow to a light receiving side of the photo relay is small in the solar cell mode described above, and it is not easy to operate the timer using the weak current.

### BRIEF DESCRIPTION OF THE DRAWINGS

FIG. 1 is a block diagram illustrating an overall configuration of a semiconductor switch according to an embodiment;

FIG. 2 is a detailed circuit diagram of an electromotive force generation circuit;

FIG. 3 is an equivalent circuit diagram of a current generation circuit of FIG. 2;

FIG. 4 is a circuit diagram illustrating an example of a specific circuit configuration of a protection circuit of FIG. 1;

FIG. 5A is a circuit diagram illustrating an example of a specific circuit configuration of a minute current source of FIG. 4;

FIG. 5B is a circuit diagram following FIG. 5A;

FIG. 6 is a circuit diagram illustrating an example of a specific circuit configuration of an overcurrent overheat detection circuit of FIG. 4;

FIG. 7 is a circuit diagram illustrating an example of a specific circuit configuration of an RS-F/F in a protection control circuit of FIG. 4; and

FIG. 8 is a diagram illustrating a truth table of the RS-F/F.

### DETAILED DESCRIPTION

A semiconductor switch according to an embodiment of the present disclosure includes:
an electromotive force generation circuit that generates an electromotive force by receiving light;
a first switching transistor that is connected between a first output terminal and a reference voltage node and drives a load when the electromotive force is generated;
a second switching transistor that is connected between a second output terminal and the reference voltage node and drives the load when the electromotive force is generated; and
a protection circuit that protects the first switching transistor and the second switching transistor from overcurrent and overheating using the electromotive force as a power supply voltage.

Hereinafter, embodiments of a semiconductor switch will be described with reference to the drawings. Main components of the semiconductor switch will be mainly described below, but the semiconductor switch may have components and functions that are not illustrated or described. The following description does not exclude the components and functions that are not illustrated or described.

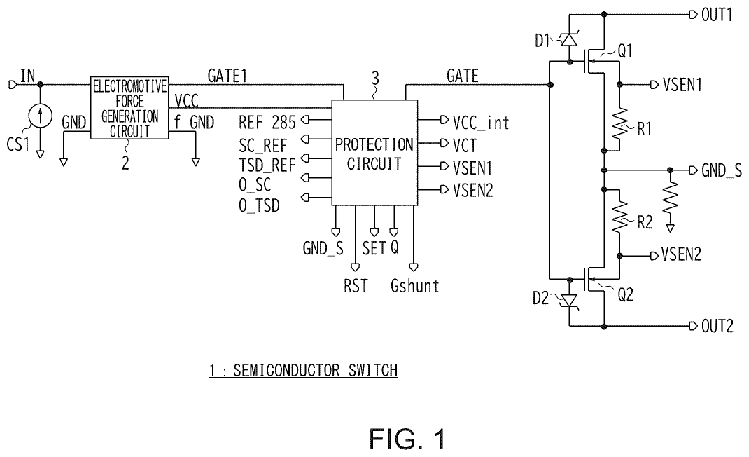

FIG. 1 is a block diagram illustrating an overall configuration of a semiconductor switch 1 according to an embodiment. As illustrated in FIG. 1, the semiconductor switch 1 according to the embodiment includes an electromotive force generation circuit 2, a first switching transistor Q1, a second switching transistor Q2, and a protection circuit 3.

The electromotive force generation circuit 2 includes a light emitting element and a light receiving element, receives light emitted from the light emitting element by the light receiving element, and generates an electromotive force by light reception. The light emitting element is, for example, an LED. The light receiving element is, for example, a photodiode. Hereinafter, an example in which the photodiode is used as the light receiving element will be described. The photodiode has a plurality of operation modes, and one of the plurality of operation modes is called a solar cell mode. The photodiode generates an electromotive force when receiving light in the solar cell mode. The electromotive force generation circuit 2 according to the present embodiment operates, for example, the photodiode in the solar cell mode.

A current source CS1 that causes a current to flow through the light emitting element is connected to the electromotive force generation circuit 2. The electromotive force generation circuit 2 outputs an electromotive force VCC and a GATE1 signal for setting a voltage of a GATE wiring connected to a gate of the first switching transistor Q1 and a gate of the second switching transistor Q2.

The first switching transistor Q1 is connected between a VSEN1 terminal and a reference voltage node (for example, a ground node), and drives a load (not illustrated) based on the electromotive force generated by the electromotive force generation circuit 2.

The second switching transistor Q2 is connected between a VSEN2 terminal and a reference voltage node (for example, a ground node), and drives a load (not illustrated) based on the electromotive force generated by the electromotive force generation circuit 2.

The first switching transistor Q1 and the second switching transistor Q2 are, for example, NMOS transistors. A first resistor R1 is connected between a body of the first switching transistor Q1 and the reference voltage node (for example, the ground node GND_S). A Zener diode D1 is connected between the gate and a drain of the first switching transistor Q1. An anode of the Zener diode D1 is connected to the gate of the first switching transistor Q1, and a cathode of the Zener diode D1 is connected to the drain of the first switching transistor Q1. A first overcurrent detection signal VSEN1 is output from the VSEN1 terminal connected to the body of the first switching transistor Q1.

A second resistor R2 is connected between a body of the second switching transistor Q2 and the reference voltage node (for example, the ground node GND_S). A Zener diode D2 is connected between the gate and a drain of the second switching transistor Q2. An anode of the Zener diode D2 is connected to the gate of the second switching transistor Q2, and a cathode of the Zener diode D2 is connected to the drain of the second switching transistor Q2. A second overcurrent detection signal VSEN2 is output from the VSEN2 terminal connected to the body of the second switching transistor Q2.

The first overcurrent detection signal VSEN1 and the second overcurrent detection signal VSEN2 described above are signals that go to a high level at the time of overcurrent detection.

The protection circuit 3 protects the first switching transistor Q1 and the second switching transistor Q2 from overcurrent and overheating using the electromotive force VCC generated by the electromotive force generation circuit 2 as a power supply voltage. The protection circuit 3 generates a first reference voltage SC_REF, a second reference voltage TSD_REF, a third reference voltage REF_285, and a fourth reference voltage VCT by using the electromotive force VCC generated by the electromotive force generation circuit 2. The first reference voltage SC_REF is used to detect an overcurrent. The second reference voltage TSD_REF is used to detect overheating. The fourth reference voltage VCT is a low voltage signal generated from the third reference voltage REF_285.

The protection circuit 3 outputs an overcurrent monitor signal O_SC indicating whether overcurrent is determined and an overheat monitor signal O_TSD indicating whether overheating is determined. The overcurrent monitor signal O_SC is, for example, a signal that goes to a low level when it is determined as overcurrent. The overheat monitor signal O_TSD is, for example, a signal that goes to the low level when it is determined as overheating.

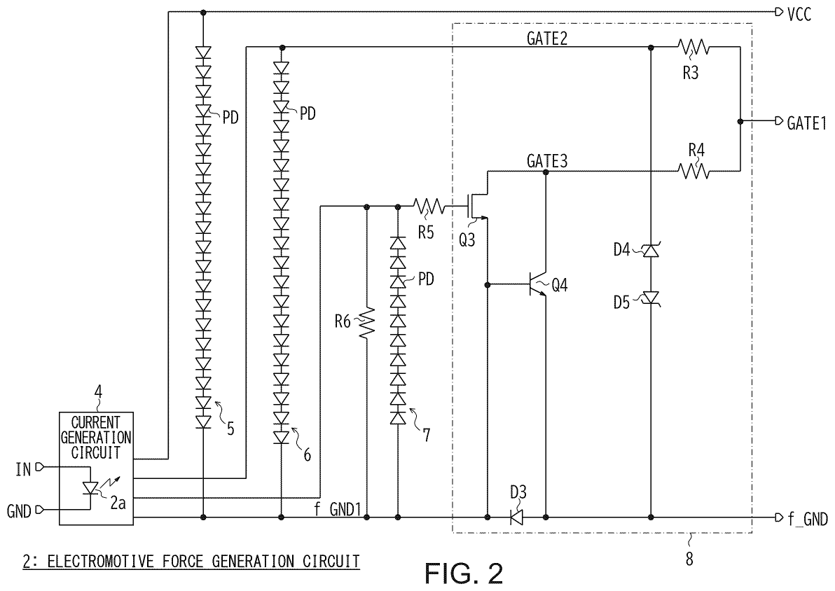

FIG. 2 is a detailed circuit diagram of the electromotive force generation circuit 2. As illustrated in FIG. 2, the electromotive force generation circuit 2 includes a current generation circuit 4, a first photodiode array 5, a second photodiode array 6, a third photodiode array 7, an OFF control circuit 8, and resistors R5 and R6.

The gate of the first switching transistor Q1 and the gate of the second switching transistor Q2 are connected with the GATE wiring. A GATE1 wiring connected to the GATE wiring via an analog switch to be described later is branched into a GATE2 wiring and a GATE3 wiring via resistors R3 and R4.

An anode of a diode D3 is connected to an f_GND node. In the present specification, a cathode of the diode D3 is referred to as an f_GND1 node.

As will be described later, the current generation circuit 4 generates a current when receiving light emitted from a light emitting element 2a. The generated current flows through the first photodiode array 5, the second photodiode array 6, and the third photodiode array 7.

Each of the first photodiode array 5, the second photodiode array 6, and the third photodiode array 7 has a configuration in which a plurality of photodiodes PD are connected in series. The first photodiode array 5 and the second photodiode array 6 have the same direction of the plurality of photodiodes PD connected in series, whereas the third photodiode array 7 has the plurality of photodiodes PD connected in series in a direction opposite to the first photodiode array 5 and the second photodiode array 6.

More specifically, the first photodiode array 5 includes the plurality of photodiodes PD connected in series between a VCC node and the f_GND1 node, an anode of each photodiode PD is arranged on the VCC node side, and a cathode is arranged on the f_GND1 node side.

The second photodiode array 6 includes the plurality of photodiodes PD connected in series between the GATE2 wiring and the f_GND1 node, an anode of each photodiode PD is arranged on the GATE2 wiring side, and a cathode is arranged on the f_GND1 node side.

The third photodiode array 7 includes the plurality of photodiodes PD connected in series between an input node of the OFF control circuit 8 and the f_GND1 node, an anode of each photodiode PD is arranged on the f_GND1 node side, and a cathode is arranged on the input node side of the OFF control circuit 8.

The OFF control circuit 8 includes an NMOS transistor Q3, an NPN transistor Q4, the diode D3, Zener diodes D4 and D5, and the resistors R3 and R4.

The NMOS transistor Q3 is of a depression type, a current flows between a drain and a source of the NMOS transistor Q3 even when a gate voltage is 0 V or less, and a voltage level of the GATE1 wiring becomes a ground voltage. The third photodiode array and the resistor R6 are connected in parallel to a gate of the NMOS transistor Q3 via the resistor R5. The GATE3 wiring is connected to the drain of the NMOS transistor Q3. A base of the NPN transistor Q4 and the f_GND1 node are connected to the source of the NMOS transistor Q3. An emitter of the NPN transistor Q4 is connected to the ground node f_GND, and a collector is connected to the GATE3 wiring.

Between the GATE2 wiring and the ground node f_GND, the two Zener diodes D4 and D5 are connected in series in opposite directions to each other.

Next, the operation of the electromotive force generation circuit 2 will be described. When the light emitting element 2a does not emit light, a current flows between the drain and the source of the NMOS transistor Q3 because the NMOS transistor Q3 in the OFF control circuit 8 is of a depression type, and the GATE1 wiring and the GATE wiring have a voltage level close to the ground voltage. Therefore, both the first switching transistor Q1 and the second switching transistor Q2 in FIG. 1 are turned off.

When the light emitting element 2a emits light, an electromotive force is generated at both ends of the first photodiode array 5, and the electromotive force is output from a VCC wiring. In addition, when the light emitting element 2a emits light, an electromotive force is generated at both ends of the second photodiode array 6, and the voltage level of the GATE1 wiring increases. Further, when the light emitting element 2a emits light, an electromotive force is generated at both ends of the third photodiode array 7, the gate voltage of the NMOS transistor Q3 in the OFF control circuit 8 becomes a negative voltage, the NMOS transistor Q3 is turned off, and a current does not flow between the drain and the source. Therefore, the voltage level of the GATE1 wiring increases, and the first switching transistor Q1 and the second switching transistor Q2 are turned on. As a result, the first switching transistor Q1 and the second switching transistor Q2 can drive a load.

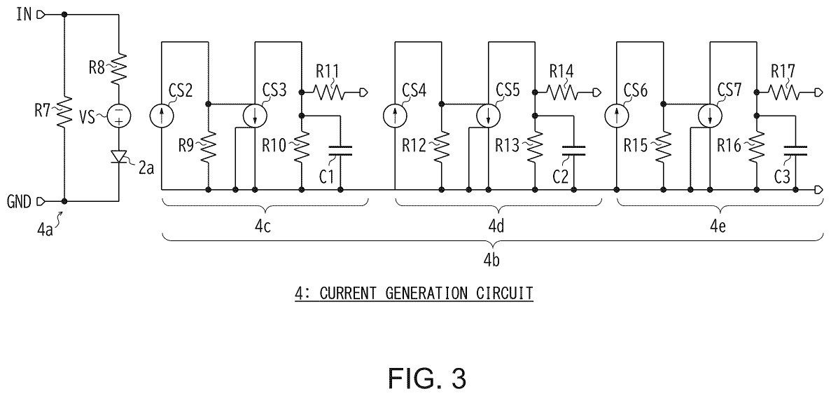

FIG. 3 is an equivalent circuit diagram of the current generation circuit 4 of FIG. 2. The current generation circuit 4 includes a light emitting circuit 4a and a light receiving circuit 4b. The light emitting circuit 4a includes the light emitting element 2a and the current source CS1. As illustrated in FIG. 3, the current source CS1 can be equivalently represented by two resistors R7 and R8 and a voltage source VS.

The light receiving circuit 4b includes a first current generation unit 4c including the first photodiode array 5, a second current generation unit 4d including the second photodiode array 6, and a third current generation unit 4e including the third photodiode array 7.

The first current generation unit 4c includes a first current source CS2, a second current source CS3, resistors R9, R10, and R11, and a capacitor C1. The first current source CS2 and the resistor R9 are connected in series, the second current source CS3, the resistor R10, and the capacitor C1 are connected in parallel, and the resistor R11 is connected in series to this parallel circuit.

The second current generation unit 4d includes a third current source CS4, a fourth current source CS5, resistors R12, R13, and R14, and a capacitor C2. The third current generation unit 4e includes a fifth current source CS6, a sixth current source CS7, resistors R15, R16, and R17, and a capacitor C3. The circuit configurations of the second current generation unit 4d and the third current generation unit 4e are the same as the circuit configuration of the first current generation unit 4c.

A current generated by the electromotive force generated in the first photodiode array 5 flows through the first current generation unit 4c. A current generated by the electromotive force generated in the second photodiode array 6 flows through the second current generation unit 4d. A current generated by the electromotive force generated in the third photodiode array 7 flows through the third current generation unit 4e. The first current source CS2 and the second current source CS3 in the first current generation unit 4c equivalently represent the current generated by the electromotive force generated in the first photodiode array 5. The third current source CS4 and the fourth current source CS5 in the second current generation unit 4d equivalently represent the current generated by the electromotive force generated in the second photodiode array 6. The fifth current source CS6 and the sixth current source CS7 connected in a different direction in the third current generation unit 4e equivalently represent the current generated by the electromotive force generated in the third photodiode array 7.

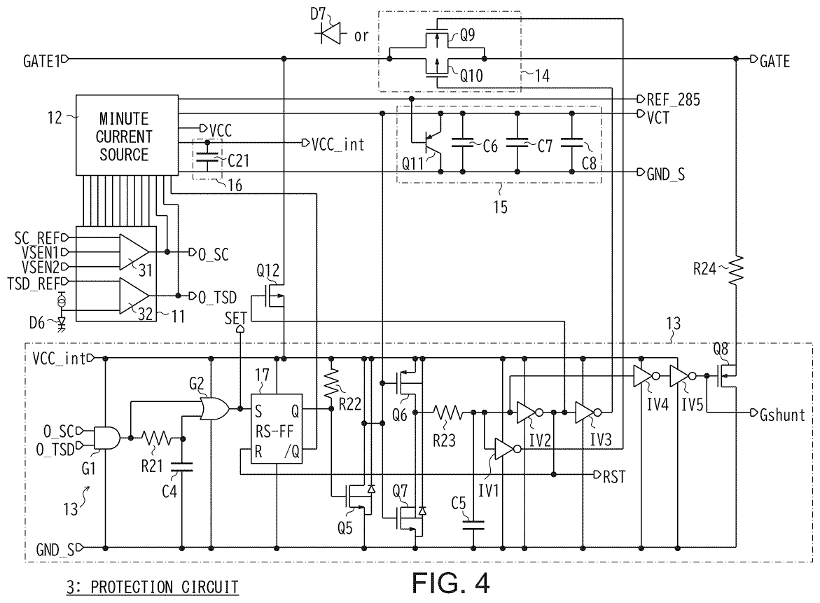

FIG. 4 is a circuit diagram illustrating an example of a specific circuit configuration of the protection circuit 3 of FIG. 1. As illustrated in FIG. 4, the protection circuit 3 includes an overcurrent overheat detection circuit 11, a minute current source 12, a protection control circuit 13, an analog switch 14, a low-voltage holding circuit 15, and an internal power supply voltage holding circuit 16.

The overcurrent overheat detection circuit 11 includes a comparator 31 that detects overcurrent, a comparator 32 that detects overheating, and a diode D6 that generates a detection voltage for overheat detection. The comparator 31 outputs an overcurrent detection signal O_SC that goes to the low level at the time of overcurrent detection. The comparator 32 outputs an overheat detection signal O_TSD that goes to the low level at the time of overheat detection. A detailed configuration of the overcurrent overheat detection circuit 11 will be described later.

The minute current source 12 generates a minute current using, as a power supply voltage, the electromotive force VCC generated in the first photodiode array 5 in the electromotive force generation circuit 2, and supplies the minute current to the overcurrent overheat detection circuit 11. The minute current generated by the minute current source 12 is, for example, about several 10 nA. A detailed configuration of the minute current source 12 will be described later.

The protection control circuit 13 forcibly turns off the first switching transistor Q1 and the second switching transistor Q2 when at least one of overcurrent and overheating is detected by the protection circuit 3. The protection control circuit 13 includes an AND gate G1, a resistor R21, a capacitor C4, an OR gate G2, an RS flip-flop (hereinafter, RS-F/F) 17, a resistor R22, an NMOS transistor Q5, a PMOS transistor Q6, an NMOS transistor Q7, a resistor R23, a capacitor C5, inverters IV1 to IV5, and an NMOS transistor Q8. Bodies of the transistors Q5 and Q7 are connected to the VCC_int node through the respective body diodes. A body of the transistor Q6 is connected to the VCC_int.

The AND gate G1 outputs a logical product signal of the overcurrent detection signal O_SC and the overheat detection signal O_TSD. The output of the AND gate G1 goes to the low level when at least one of overcurrent and overheating is detected.

The output signal of the AND gate G1 is input to one input terminal of the OR gate G2. One end of the resistor R21 and one end of the capacitor C4 are connected to the other input terminal of the OR gate G2. The other end of the resistor R21 is connected to an output node of the AND gate G1, and the other end of the capacitor C4 is connected to the ground node GND_S. As a result, an output of the OR gate G2 transitions to the low level after waiting for the time corresponding to a time constant of a resistance value of the resistor R21 and a capacitance of the capacitor C4 after the output signal of the AND gate G1 transitions from high to low. In this manner, the OR gate G2, the resistor R21, and the capacitor C4 function as a timer that waits for the time corresponding to the time constant depending on the resistance value of the resistor R21 and the capacitance of the capacitor C4.

The output signal of the OR gate G2 is input to a set(S) terminal of the RS-F/F 17. A reset signal RST to be described later is input to a reset (R) terminal of the RS-F/F 17.

When the S terminal goes to the low level, the RS-F/F 17 goes to a set state, and a Q terminal goes to the high level. As a result, the NMOS transistor Q5 is turned on, and a drain of the NMOS transistor Q5 becomes the ground level. Therefore, the PMOS transistor Q6 is turned on, and a drain of the PMOS transistor Q6 becomes a high-level voltage.

One end of the resistor R23 is connected to the drain of the PMOS transistor Q6, and the capacitor C5 is connected between the other end of the resistor R23 and the ground node GND_S. When a voltage level of the drain of the PMOS transistor Q6 changes, signal logic of each of output nodes of the inverters IV1, IV2, IV3, IV4, and IV5 changes with a time delay corresponding to a time constant determined by a resistance value of the resistor R23 and a capacitance of the capacitor C5.

For example, when the drain of the PMOS transistor Q6 becomes the high-level voltage, the signal logic of the output nodes of the inverters IV4 and IV5 changes slightly later, and a gate signal Gshunt of the NMOS transistor Q8 becomes the high-level voltage. As a result, the NMOS transistor Q8 is turned on, and the voltage level of the GATE wiring is lowered. Therefore, the first switching transistor Q1 and the second switching transistor Q2 are forcibly turned off.

At this time, since an output of the inverter IV3 becomes the high level and an output of the inverter IV1 becomes the low level, both the NMOS transistor Q9 and the PMOS transistor Q10 constituting the analog switch 14 are turned off. When the analog switch 14 is turned off, even if the GATE1 signal output from the electromotive force generation circuit 2 is at the high level, the GATE wiring connected to the gate of the first switching transistor Q1 and the gate of the second switching transistor Q2 does not go to the high level, and the first switching transistor Q1 and the second switching transistor Q2 can be reliably turned off.

A diode D7 may be connected instead of the analog switch 14. An anode of the diode D7 is connected to the GATE wiring, and a cathode of the diode D7 is connected to the GATE1 wiring. The diode D7 functions as a blocking diode and prevents the voltage of the GATE1 wiring from being supplied to the gate of the first switching transistor Q1 and the gate of the second switching transistor Q2. As described above, when the protection circuit 3 forcibly turns off the first switching transistor Q1 and the second switching transistor Q2, the analog switch 14 or the diode D7 functions as a voltage cut-off circuit that cuts off the GATE wiring (first wiring) connecting the output node of the protection circuit 3 with the gate of the first switching transistor Q1 and the gate of the second switching transistor Q2 from the GATE1 wiring (second wiring) that supplies the electromotive force.

The low-voltage holding circuit 15 includes a PNP transistor Q11 and three capacitors C6, C7, and C8 connected in parallel between an emitter and a collector of the PNP transistor Q11. A fourth reference voltage VCT generated by the minute current source 12 described later is supplied to the emitter of the PNP transistor Q11.

The third reference voltage REF_285 having a predetermined voltage level is input to a base of the PNP transistor Q11. Based on the third reference voltage REF_285 input to the base, the PNP transistor Q11 holds the fourth reference voltage VCT having a voltage level lower than the voltage level of the third reference voltage REF_285 between the emitter and the collector.

The internal power supply voltage holding circuit 16 includes a capacitor C21 that holds an internal power supply voltage VCC_int generated by the minute current source 12.

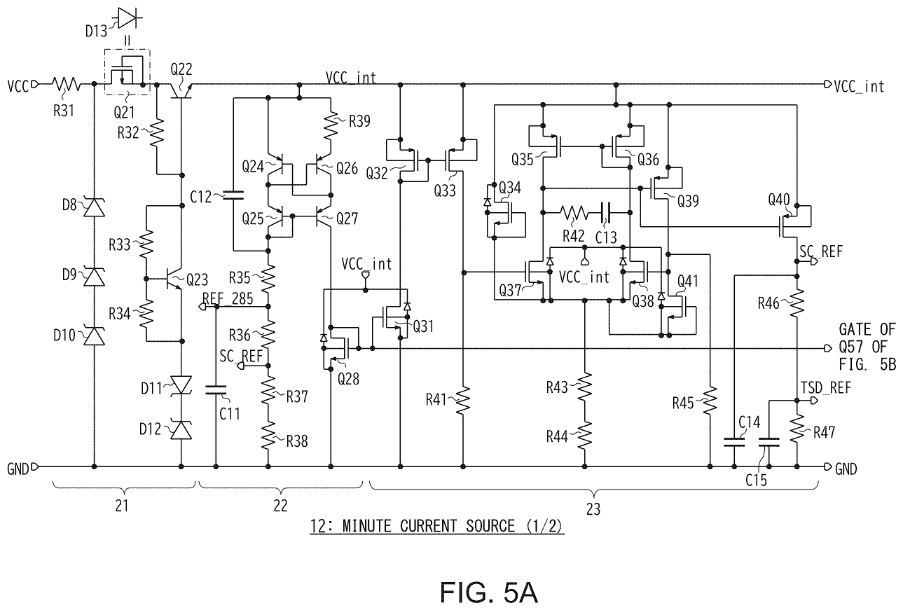

FIGS. 5A and 5B are circuit diagrams illustrating an example of a specific circuit configuration of the minute current source 12 of FIG. 4. All the circuits in FIGS. 5A and 5B constitute the minute current source 12. As illustrated in FIGS. 5A and 5B, the minute current source 12 includes an internal power supply voltage generation circuit 21, a first reference voltage generation circuit 22, a second reference voltage generation circuit 23, a third reference voltage generation circuit 24, and a minute current generation circuit 25.

The internal power supply voltage generation circuit 21 includes a resistor R31, Zener diodes D8, D9, and D10, a diode-connected depression type PMOS transistor Q21, an NPN transistor Q22, a resistor R32, an NPN transistor Q23, resistors R33 and R34, and Zener diodes D11 and D12.

The VCC wiring is connected to one end of the resistor R31. The three Zener diodes D8, D9, and D10 are connected in series between the other end of the resistor R31 and the ground node GND. Cathodes of these Zener diodes D8, D9, and D10 are arranged on the other end side of the resistor R31, and anodes are arranged on the ground node GND side.

The diode-connected PMOS transistor Q21 functions as a blocking diode D13. The blocking diode D13 is provided to separate the electromotive force VCC and the internal power supply voltage VCC_int, an anode of the blocking diode D13 is arranged on the wiring side of the electromotive force VCC, and a cathode is arranged on the wiring side of the internal power supply voltage VCC_int.

A collector of the NPN transistor Q22 is connected to the cathode of the blocking diode D13. The resistor R32 is connected between a base and a collector of the NPN transistor Q22. The base of the NPN transistor Q22 is connected to a collector of the NPN transistor Q23. The resistor R33 is connected between the collector and a base of the NPN transistor Q23, and the resistor R34 is connected between the base and an emitter of the NPN transistor Q23. The two Zener diodes D11 and D12 are connected in series in opposite directions to each other between the emitter of the NPN transistor Q23 and the ground node GND.

The first reference voltage generation circuit 22 includes capacitors C11 and C12, PNP transistors Q24 to Q27, resistors R35 to R39, and an NMOS transistor Q28. An emitter of the PNP transistor Q24 is connected to a VCC_int node. A collector of the PNP transistor Q24 is connected to an emitter of the PNP transistor Q25. A collector and a base of the PNP transistor Q25 are short-circuited, and the capacitor C12 is connected between this short-circuit node and the VCC_int node. The four resistors R35 to R38 are connected in series between the collector of the PNP transistor Q25 and the ground node GND.

The resistor R39 is connected between an emitter of the PNP transistor Q26 and the VCC_int node. A collector of the PNP transistor Q26 and an emitter of the PNP transistor Q27 are connected, and a base of the PNP transistor Q24 is connected to this connection node. A base of the PNP transistor Q26, the collector of the PNP transistor Q24, and an emitter of the PNP transistor Q25 are connected in common. A collector of the PNP transistor Q27 is connected to a drain of the NMOS transistor Q28. A source of the NMOS transistor Q28 is connected to the ground node GND.

The third reference voltage REF_285 is output from between the resistor R35 and the resistor R36. The capacitor C11 is connected between a node that outputs the third reference voltage REF_285 and the ground node GND. The first reference voltage SC_REF is output from between the resistor R36 and the resistor R37.

The second reference voltage generation circuit 23 includes an NMOS transistor Q31, two PMOS transistors Q32 and Q33, a resistor R41, an NMOS transistor Q34, two PMOS transistors Q35 and Q36, two NMOS transistors Q37 and Q38, two PMOS transistors Q39 and Q40, an NMOS transistor Q41, resistors R42 to R47, and capacitors C13 to C15.

A gate and the drain of the NMOS transistor Q28 are short-circuited, and the gate of the NMOS transistor Q28 is connected to a gate of the NMOS transistor Q31. As described above, the NMOS transistor Q31 and the NMOS transistor Q28 constitute a current mirror circuit.

A drain of the NMOS transistor Q31 is connected to a drain and a gate of the PMOS transistor Q32. A source of the PMOS transistor Q32 is connected to the VCC_int node. The gate of the PMOS transistor Q32 is connected to a gate of the PMOS transistor Q33, and the PMOS transistor Q32 and the PMOS transistor Q33 constitute a current mirror circuit. A source of the PMOS transistor Q33 is connected to the VCC_int node. The resistor R41 is connected between a drain of the PMOS transistor Q33 and the ground node GND.

A drain of the NMOS transistor Q34 is connected to the VCC_int node, and a source and a gate of the NMOS transistor Q34 are short-circuited.

A source of the PMOS transistor Q35 is connected to the VCC_int node, and a gate is connected to a gate and a drain of the PMOS transistor Q36. In this manner, the PMOS transistor Q35 and the PMOS transistor Q36 constitute a current mirror circuit.

A drain of the PMOS transistor Q35 is connected to a drain of the NMOS transistor Q37. The drain of the PMOS transistor Q36 is connected to a drain of the NMOS transistor Q38. Sources of the NMOS transistors Q37 and Q38 are connected to each other. In addition, the resistor R42 and the capacitor C13 are connected in series between the drains of the NMOS transistors Q37 and Q38.

A source of the PMOS transistor Q39 is connected to the VCC_int node. A gate of the PMOS transistor Q39 is connected to the drains of the transistors Q35 and Q37. A drain of the PMOS transistor Q39 is connected to a drain of the NMOS transistor Q41. A gate and a source of the NMOS transistor Q41 are short-circuited.

The source of the NMOS transistor Q37, the source of the NMOS transistor Q38, and the gate and the source of the NMOS transistor Q41 are connected in common, and the two resistors R43 and R44 are connected in series between this connection node and the ground node GND. The resistor R45 is connected between the drain of the NMOS transistor Q41 and the ground node GND. Bodies of the transistors Q28, Q31, Q34, Q37, Q38 and Q41 are connected to the VCC_int node through the respective body diodes.

A source of the PMOS transistor Q40 is connected to the VCC_int node. A gate of the PMOS transistor Q40 is connected to the gate of the PMOS transistor Q39 and the drains of the transistors Q35 and Q37.

The two resistors R46 and R47 are connected in series between a drain of the PMOS transistor Q40 and the ground node GND. The capacitor C15 is connected in parallel to the resistor R47. The capacitor C14 is connected between a connection node of the drain of the PMOS transistor Q40 and the resistor R46 and the ground node GND.

The first reference voltage SC_REF is input to the connection node of the drain of the PMOS transistor Q40 and the resistor R46. The second reference voltage TSD_REF is output from a connection node between the resistor R46 and the resistor R47.

The third reference voltage generation circuit 24 illustrated in FIG. 5B includes six PMOS transistors Q51 to Q56, an NMOS transistor Q57, and a PNP transistor Q58.

A gate and a drain of the PMOS transistor Q53 are short-circuited, and gates of the six PMOS transistors Q51 to Q56 are connected to this short-circuit node. Therefore, the six PMOS transistors Q51 to Q56 constitute a current mirror circuit.

A source of the PMOS transistor Q51 is connected to the VCC_int node, and a drain of the PMOS transistor Q51 is connected to a source of the PMOS transistor Q52. A drain of the PMOS transistor Q52 is connected to a source of the PMOS transistor Q53.

A source of the PMOS transistor Q54 is connected to the VCC_int node, and a drain of the PMOS transistor Q54 is connected to a source of the PMOS transistor Q55. A drain of the PMOS transistor Q55 is connected to a source of the PMOS transistor Q56.

The gate and the drain of the PMOS transistor Q53 are connected to a drain of the NMOS transistor Q57. A source of the NMOS transistor Q57 is connected to the ground node GND.

A drain of the PMOS transistor Q56 is connected to an emitter and a base of the PNP transistor Q58. A collector of the PNP transistor Q58 is connected to the ground node GND. The fourth reference voltage VCT is output from the drain of the PMOS transistor Q56.

The minute current generation circuit 25 includes a total of 14 PMOS transistors Q61 to Q74 constituting a current mirror circuit and an NMOS transistor Q75.

A source of the PMOS transistor Q61 is connected to the VCC_int node, a gate and a drain are short-circuited, and a drain of the NMOS transistor Q75 is connected to this short-circuit node. A source of the NMOS transistor Q75 is connected to the ground node GND. A gate of the NMOS transistor Q75 is connected to a gate of the NMOS transistor Q57.

Sources of the 13 PMOS transistors Q62 to Q74 are connected to the VCC_int node, gates are connected in common, and the gate of the PMOS transistor Q61 is also connected to this connection node.

A minute current is output from each of drains of the 13 PMOS transistors Q62 to Q74. Out of the 13 minute currents, 12 minute currents are supplied to the overcurrent overheat detection circuit 11, and the remaining one minute current is supplied to the protection circuit 3.

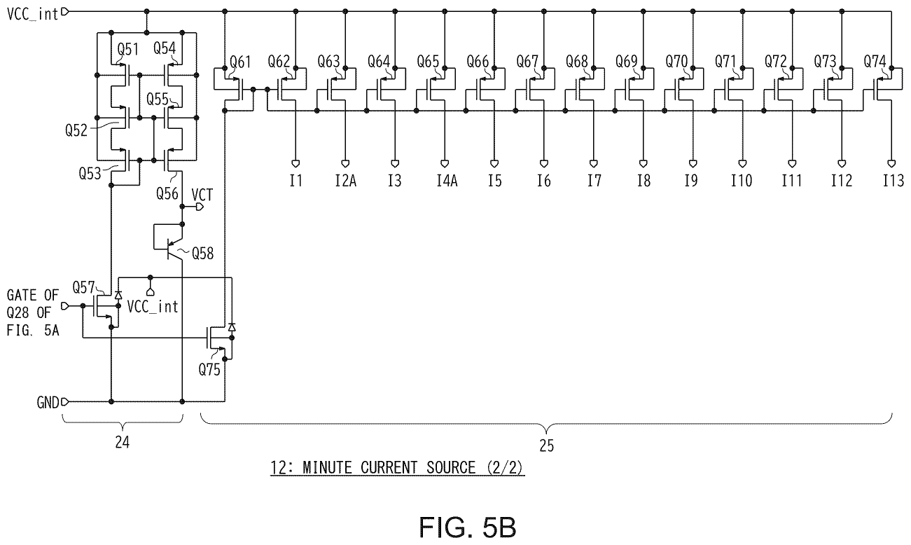

FIG. 6 is a circuit diagram illustrating an example of a specific circuit configuration of the overcurrent overheat detection circuit 11 of FIG. 4. As illustrated in FIG. 6, the overcurrent overheat detection circuit 11 includes a first comparator 31a and a second comparator 31b constituting a comparator 31 for overcurrent detection, and a third comparator 32 for overheat detection. The first comparator 31a compares a voltage level of the first overcurrent detection signal VSEN1 with a voltage level of the first reference voltage SC_REF, and outputs an error signal indicating a comparison result. The first comparator 31a outputs the error signal at the low level when the voltage level of the first overcurrent detection signal VSEN1 is higher than the voltage level of the first reference voltage SC_REF.

The second comparator 31b compares a voltage level of the second overcurrent detection signal VSEN2 with the voltage level of the first reference voltage SC_REF, and outputs an error signal indicating a comparison result. The second comparator 31b outputs the error signal at the low level when the voltage level of the second overcurrent detection signal VSEN2 is higher than the voltage level of the first reference voltage SC_REF.

The first wiring that transmits the error signal output from the first comparator 31a and the second wiring that transmits the error signal output from the second comparator 31b are subjected to wired-OR, and the overcurrent monitor signal O_SC is generated. The overcurrent monitor signal O_SC goes to the low level, for example, when it is determined as overcurrent.

In a normal diode, since a forward voltage decreases as the temperature increases, it is possible to determine whether the diode is overheated by comparing the forward voltage of the diode with a predetermined reference voltage. Therefore, the third comparator 32 compares a forward voltage of the diode D6 with a fifth reference voltage and outputs an error signal indicating a comparison result. When the forward voltage of the diode becomes lower than the fifth reference voltage due to overheating, the third comparator 32 outputs the overheat detection signal O_TSD at the low level.

The first comparator 31a includes resistors R51 and R52, a Zener diode D21, four PNP transistors Q81 to Q84, two NPN transistors Q85 and Q86, a capacitor C21, an NPN transistor Q87, a capacitor C21, and a resistor R53.

The first overcurrent detection signal VSEN1 is input to a base of the PNP transistor Q81 via the resistor R51. The resistor R52 and the Zener diode D21 are connected in parallel between the base of the PNP transistor Q81 and the ground node GND.

A minute current I1 from the minute current source 12 is supplied to an emitter of the PNP transistor Q81. The emitter of the PNP transistor Q81 is connected to a base of the PNP transistor Q82. A minute current I2A from the minute current source 12 is supplied to an emitter of the PNP transistor Q82 and an emitter of the PNP transistor Q83.

A collector of the PNP transistor Q82 is connected to a collector and a base of the NPN transistor Q85. A collector of the PNP transistor Q83 is connected to a collector of the NPN transistor Q86. The base of the NPN transistor Q85 and a base of the NPN transistor Q86 are connected to each other, and the NPN transistor Q85 and the NPN transistor Q86 constitute a current mirror circuit.

A minute current I3 from the minute current source 12 is supplied to a base of the PNP transistor Q83 and an emitter of the PNP transistor Q84. A collector of the PNP transistor Q84 is connected to the ground node GND. The first reference voltage SC_REF is supplied to a base of the PNP transistor Q84 via the resistor R53.

The collector of the PNP transistor Q83 and the collector of the NPN transistor Q86 are connected to a base of the NPN transistor Q87. The overcurrent monitor signal O_SC is output from a collector of the NPN transistor Q87.

The second comparator 31b includes resistors R54 and R55, a Zener diode D22, four PNP transistors Q88 to Q91, two NPN transistors Q92 and Q93, a capacitor C22, an NPN transistor Q94, and a resistor R56.

The second overcurrent detection signal VSEN2 is input to a base of the PNP transistor Q88 via the resistor R54. The resistor R55 and the Zener diode D22 are connected in parallel between the base of the PNP transistor Q88 and the ground node GND.

A minute current I4A from the minute current source 12 is supplied to an emitter of the PNP transistor Q88. The emitter of the PNP transistor Q88 is connected to a base of the PNP transistor Q89. A minute current I5 from the minute current source 12 is supplied to an emitter of the PNP transistor Q89 and an emitter of the PNP transistor Q90.

A collector of the PNP transistor Q89 is connected to a collector and a base of the NPN transistor Q92. A collector of the PNP transistor Q90 is connected to a collector of the NPN transistor Q93. The base of the NPN transistor Q92 and a base of the NPN transistor Q93 are connected to each other, and the NPN transistor Q92 and the NPN transistor Q93 constitute a current mirror circuit.

A minute current I6 from the minute current source 12 is supplied to a base of the PNP transistor Q90 and an emitter of the PNP transistor Q91. A collector of the PNP transistor Q91 is connected to the ground node GND. The first reference voltage SC_REF is supplied to a base of the PNP transistor Q91 via the resistor R56.

The collector of the PNP transistor Q90 and the collector of the NPN transistor Q93 are connected to a base of the NPN transistor Q94. A collector of the NPN transistor Q94 is connected to the collector of the NPN transistor Q87, and outputs the overcurrent monitor signal O_SC obtained by subjecting a comparison result signal of the first comparator 31a and a comparison result signal of the second comparator 31b to wired-OR. A minute current I7 from the minute current source 12 is supplied to an output node of the overcurrent monitor signal O_SC.

The third comparator 32 includes a diode-connected NPN transistor Q95, four PNP transistors Q96 to Q99, two NPN transistors Q100 and Q101, a capacitor C23, a resistor R58, and an NPN transistor Q102.

A minute current I8 from the minute current source 12 is supplied to a base and a collector (anode of the diode D6 shown in FIG. 4) of the diode-connected NPN transistor Q95. An emitter of the NPN transistor Q95 is connected to the ground node GND. The forward voltage of the diode D6 including the NPN transistor Q95 is input to a base of the PNP transistor Q96 via the resistor R57. The second reference voltage TSD_REF is input to a base of the PNP transistor Q99 via the resistor R58. An emitter of the PNP transistor Q96 is connected to a base of the PNP transistor Q97, and an emitter of the PNP transistor Q99 is connected to a base of the PNP transistor Q98. Emitters of the PNP transistors Q97 and Q98 are connected to each other, and supplied with a minute current I10 from the minute current source 12.

A collector of the PNP transistor Q97 is connected to a collector of the NPN transistor Q100, and a collector of the PNP transistor Q98 is connected to a collector and a base of the NPN transistor Q101. The NPN transistors Q100 and Q101 constitute a current mirror circuit.

The capacitor C23 is connected between the base of the PNP transistor Q99 and the ground node GND. The collector of the PNP transistor Q97 and the collector of the NPN transistor Q100 are connected to a base of the NPN transistor Q102. A minute current I12 is supplied from the minute current source 12 to a collector of the NPN transistor Q102. An emitter of the NPN transistor Q102 is connected to the ground node GND. The overheat monitor signal O_TSD is output from the collector of the NPN transistor Q102.

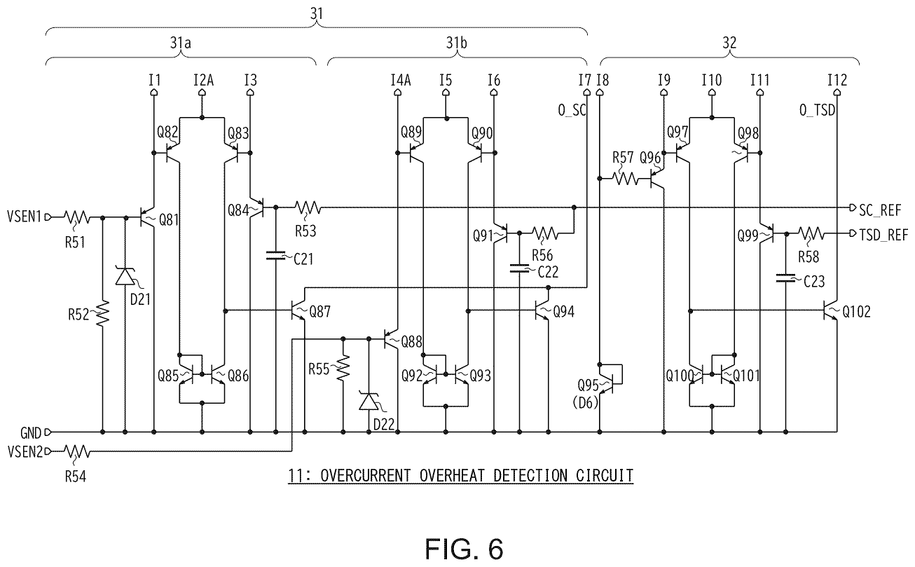

FIG. 7 is a circuit diagram illustrating an example of a specific circuit configuration of the RS-F/F 17 in the protection control circuit 13 of FIG. 4. As illustrated in FIG. 7, the RS-F/F 17 includes a 3-input NAND gate G3, a 2-input NAND gate G4, and an inverter IV10. To the 3-input NAND gate G3, VDD, a set signal S, and an output signal of the 2-input NAND gate G4 are input, and a NAND signal of these signals is output. The output signal of the 3-input NAND gate G3 is output from the Q terminal, and a signal obtained by inverting the output signal by the inverter IV10 is output from a/Q terminal. Reference sign VDD in FIG. 7 is the internal power supply voltage VCC_int in FIG. 4.

The output signal of the 3-input NAND gate G3 and the reset signal R are input to the 2-input NAND gate G4, and a NAND signal of these signals is output. The output signal of the 2-input NAND gate G4 is input to the 3-input NAND gate G3.

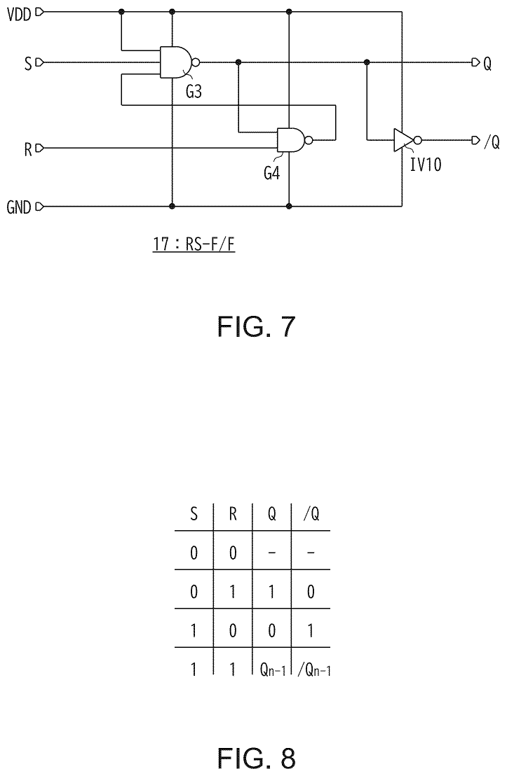

FIG. 8 is a diagram illustrating a truth table of the RS-F/F 17. When the set signal S goes to the low level, the Q terminal goes to the high level, and when the reset signal R goes to the low level, the/Q terminal goes to the high level.

As described above, in the present embodiment, the first switching transistor Q1 and the second switching transistor Q2 can be protected from overcurrent and overheating by operating the protection circuit 3 using the electromotive force generated by light reception. According to the present embodiment, since a power supply circuit is not required to operate the protection circuit 3, the semiconductor switch 1 can be downsized, and the application range of the semiconductor switch 1 according to the present embodiment can be widened.

In addition, in the present embodiment, overcurrent is detected based on the minute current flowing in the body according to the current flowing between the drain and the source of the first switching transistor Q1 and the second switching transistor Q2, and overheating is detected by the change in the forward voltage of the diode D6, so that the overcurrent and the overheating can be accurately detected with low power consumption.

Furthermore, after at least one of overcurrent and overheating is detected, the first switching transistor Q1 and the second switching transistor Q2 are turned off after waiting for the period corresponding to the time constant depending on the resistance value of the resistor R21 and the capacitance of the capacitor C4 in the protection control circuit 13 of FIG. 4. As a result, a timer including an analog circuit can be driven using weak power, and the first switching transistor Q1 and the second switching transistor Q2 can be protected with low power consumption and a small-scale circuit configuration.

While certain embodiments have been described, these embodiments have been presented by way of example only, and are not intended to limit the scope of the disclosures. Indeed, the novel methods and systems described herein may be embodied in a variety of other forms; furthermore, various omissions, substitutions and changes in the form of the methods and systems described herein may be made without departing from the spirit of the disclosures. The accompanying claims and their equivalents are intended to cover such forms or modifications as would fall within the scope and spirit of the disclosures.

1. A semiconductor switch comprising:
an electromotive force generation circuit that generates an electromotive force by receiving light;
a first switching transistor that is connected between a first output terminal and a reference voltage node and drives a load when the electromotive force is generated;
a second switching transistor that is connected between a second output terminal and the reference voltage node and drives the load when the electromotive force is generated; and
a protection circuit that protects the first switching transistor and the second switching transistor from overcurrent and overheating using the electromotive force as a power supply voltage.

2. The semiconductor switch according to claim 1, further comprising:
a first overcurrent detection circuit that outputs a first overcurrent detection signal corresponding to a current flowing between a drain and a source of the first switching transistor; and
a second overcurrent detection circuit that outputs a second overcurrent detection signal corresponding to a current flowing between a drain and a source of the second switching transistor, wherein
the protection circuit determines whether to turn off the first switching transistor and the second switching transistor based on signal levels of the first overcurrent detection signal and the second overcurrent detection signal.

3. The semiconductor switch according to claim 2, wherein
the first overcurrent detection circuit includes a first resistor connected between a body and the source of the first switching transistor, and outputs the first overcurrent detection signal having a signal level corresponding to a voltage across both ends of the first resistor, and
the second overcurrent detection circuit includes a second resistor connected between a body and the source of the second switching transistor, and outputs the second overcurrent detection signal having a signal level corresponding to a voltage across both ends of the second resistor.

4. The semiconductor switch according to claim 2, wherein
the protection circuit includes an overcurrent determination circuit, and
the overcurrent determination circuit includes
a first comparator that compares the signal level of the first overcurrent detection signal with a predetermined first reference voltage, and
a second comparator that compares the signal level of the second overcurrent detection signal with the first reference voltage.

5. The semiconductor switch according to claim 4, further comprising:
a first wiring connected to an output node of the first comparator; and
a second wiring connected to an output node of the second comparator, wherein
a connection node between the first wiring and the second wiring generates an overcurrent detection signal generated by wired-OR of an output signal of the first comparator and an output signal of the second comparator.

6. The semiconductor switch according to claim 4, wherein
the protection circuit includes an overheat detection circuit, and
the overheat detection circuit includes
a diode for overheat detection, and
a third comparator that compares a forward voltage of the diode with a second reference voltage.

7. The semiconductor switch according to claim 6, wherein
the protection circuit includes a minute current source that generates a minute current using the electromotive force as a power supply voltage, and
each of the first comparator, the second comparator, and the third comparator is supplied with a minute current from the minute current source.

8. The semiconductor switch according to claim 6, wherein
the protection circuit includes a protection control circuit that forcibly turns off the first switching transistor and the second switching transistor when at least one of overcurrent and overheating is detected in the first comparator, the second comparator, and the third comparator.

9. The semiconductor switch according to claim 8, wherein
the protection circuit includes a timer that waits for a predetermined period after at least one of overcurrent and overheating is detected in the first comparator, the second comparator, and the third comparator, and
the protection control circuit forcibly turns off the first switching transistor and the second switching transistor after waiting for the predetermined period by the timer.

10. The semiconductor switch according to claim 9, wherein
the timer includes a resistor, a capacitor, and a logic gate circuit,
the logic gate circuit performs a logic operation between a detection signal that becomes predetermined signal logic when at least one of overcurrent and overheating is detected and a delay signal that delays a timing at which the detection signal becomes the predetermined signal logic, and
the protection circuit forcibly turns off the first switching transistor and the second switching transistor when signal logic of an output signal of the logic gate circuit changes.

11. The semiconductor switch according to claim 10, wherein
the predetermined period is adjusted by a time constant determined by a resistance value of the resistor and a capacitance of the capacitor.

12. The semiconductor switch according to claim 1, further comprising
a voltage cut-off circuit that cuts off a first wiring connecting an output node of the protection circuit with a gate of the first switching transistor and a gate of the second switching transistor from a second wiring that supplies the electromotive force when the protection circuit forcibly turns off the first switching transistor and the second switching transistor.

13. The semiconductor switch according to claim 12, wherein
the voltage cut-off circuit includes a diode having an anode connected to the gate of the first switching transistor and the gate of the second switching transistor, and a cathode connected to an output node of the electromotive force generation circuit.

14. The semiconductor switch according to claim 12, wherein
the voltage cut-off circuit includes an analog switch that switches whether the gate of the first switching transistor and the gate of the second switching transistor are connected with or cut off from an output node of the electromotive force generation circuit.

15. The semiconductor switch according to claim 1, wherein
the electromotive force generation circuit includes
a light emitting element,
a first photodiode array including two or more photodiodes that are connected in series, receive light emitted by the light emitting element, and generate an electromotive force,
a second photodiode array including two or more photodiodes that are connected in series, receive light emitted by the light emitting element, and generate an electromotive force,
a third photodiode array including two or more photodiodes that are connected in series, receive light emitted by the light emitting element, and generate an electromotive force, and
a voltage control circuit that controls a voltage of a wiring connected to a gate of the first switching transistor and a gate of the second switching transistor based on the electromotive force generated by light reception in the second photodiode array and the electromotive force generated by light reception in the third photodiode array, and
the electromotive force of the first photodiode array is used as a power supply voltage of the protection circuit.

16. The semiconductor switch according to claim 15, wherein
a connection direction of the two or more photodiodes in the first photodiode array and the second photodiode array is opposite to a connection direction of the two or more photodiodes in the third photodiode array.

17. The semiconductor switch according to claim 16, wherein
the voltage control circuit turns on both the first switching transistor and the second switching transistor when the electromotive force generated by light reception in the second photodiode array exceeds a first threshold voltage, and turns off both the first switching transistor and the second switching transistor when the electromotive force generated by light reception in the third photodiode array becomes equal to or less than a second threshold voltage.

18. The semiconductor switch according to claim 1, further comprising
a semiconductor chip incorporating the electromotive force generation circuit and the protection circuit.
